(19) United States
(12) Patent Application Publication
(10) Pub. No.: US 2010/0282288 A1
(43) Pub. Date: Nov. 11, 2010

(54) Solar Cell Interconnection on a Flexible Substrate

(75) Inventor: Arthur Cornfeld, Sandia Park, NM (US)

Correspondence Address: EMCORE CORPORATION, 1600 EUBANK BLVD, S.E., ALBUQUERQUE, NM, 87123, US

(73) Assignee: Emcore Solar Power, Inc., Albuquerque, NM (US)

(21) Appl. No.: 12/436,467

(22) Filed: May 6, 2009

(51) Int. Cl. H01L 31/042; B32B 37/12; B32B 37/02

(52) U.S. Cl. 136/244; 156/305; 156/73.1

(57) ABSTRACT

A solar cell array comprising: a substrate having a carrier surface on which a plurality of electrically conductive bonding pads are provided, the bonding pads being spaced from one another along a main direction; a plurality of solar cells, each solar cell of the plurality including a back electrode bonded to a first portion of a respective bonding pad, wherein each bonding pad comprises a second portion defining an exposed contact region not covered by the back electrode of the respective solar cell, and wherein an interconnecting lead electrically connects the second portion of the bonding pad associated with a first solar cell with an electrode of a directly adjacent second solar cell.

The substrate is an electrically insulating substrate and preferably a flexible film, made for instance of polyimide material.

### BACKGROUND OF THE INVENTION

1. Field of the Invention

The present invention relates to solar cell arrays of interconnected individual cells mounted on an electrically insulating substrate, and in particular to methods for assembling a high density solar cell arrays.

2. Description of Related Art

Solar cells are photovoltaic devices that convert sunlight directly into electrical power.

Thin-film technology has gained widespread interest in satellite and in general space applications because of their low cost, high-density packaging, and radiation resistance. Thin-film solar cells can be in general based on different semiconductors materials, such as polycrystalline or amorphous silicon, binary to quaternary alloys of III-V semiconductors, CdTe- or copper-indium-gallium selenide (CIGS) based materials. A key issue in the development of thin-film solar cells for space applications has been the production of high-power density solar modules to be used as the primary power source for spacecraft.

Especially for spacecraft applications, where a heavy supporting material should be avoided, photovoltaic modules with solar cells bonded on a flexible film have gained much attention in the past years, as they bear the advantage of being, by their very nature, of lighter weight than the conventional honeycomb structures.

Solar cells are often fabricated in single-junctions or in vertical multi-junction structures, and arranged in horizontal arrays, where the individual cells are series-connected one to another.

Inverted metamorphic solar cell structures based on III-V compound semiconductor layers, such as described in M. W. Wanlass et al., “Lattice Mismatched Approaches for High Performance III-V Photovoltaic Energy Converters” (Conference Proceedings of the 31^{st} IEEE Photovoltaic Specialists Conference, Jan. 3-7, 2005, IEEE Press, 2005), present an important conceptual starting point for the development of future commercial high efficiency solar cells. One embodiment of such a structure, described in US patent application Serial No. 2008/0245409, discloses an inverted metamorphic multifunction solar cell mounted on a flexible film. The solar cell is manufactured by providing a substrate; depositing a sequence of layers of semiconductor materials on the substrate; mounting the substrate on a flexible film; and thinning the substrate to a predetermined thickness.

### SUMMARY OF THE INVENTION

It is an object of the present invention to provide a solar cell array on a film substrate with a high packing density, preferably not lower than 85%.

It is another object of the present invention to provide a solar cell array on an electrically insulating film substrate with robust electrical interconnections.

It is still an object of the present invention to provide a high packing density solar cell array with easy-to-manufacture interconnections.

Some implementations or embodiments of the invention may achieve fewer than all of the foregoing objects.

The Applicant has observed that thin-film solar cells are fragile to handle and are in general provided with thin metallic films as contact layers on top and/or on the bottom of the semiconductor layers forming the active portion of the cell. In case of solar cell having a two-sided contact structure with a front contact and a back contact, the thickness of the layers forming the contacts is in general of less than 10 μm, and typically of a few micrometers, in order to provide a good ohmic contact.

In addition, the rigidity of bonding wires employed in the interconnections between adjacent solar cells and the weakness of the metal layer forming the back contact of an already fragile thin-film structure makes it difficult to attach the individual cells close one to another on the common substrate.

Briefly and in general terms, in an aspect, the present invention is directed to a solar cell array comprising: a substrate having a carrier surface on which a plurality of electrically conductive bonding pads are provided, the bonding pads being spaced from one another in a main direction; a plurality of solar cells, each solar cell of the plurality including a first electrode bonded to a respective bonding pad so as to make electrical contact with a first portion of the respective bonding pad, wherein each bonding pad comprises a second portion defining an exposed contact region not covered by the first electrode of the respective solar cell, and wherein an interconnecting lead electrically connects the second portion of the bonding pad associated with a first solar cell with a second electrode of a directly adjacent second solar cell.

In another aspect, briefly and in general terms, the present invention is directed to a method of assembling a solar cell array comprising: providing a substrate; forming on the substrate a plurality of spaced apart electrically conductive bonding pads; bonding a solar cell to each of said bonding pads so that a first electrode of each of the solar cells makes electrical contact with a respective first portion of each bonding pad and a second portion of each bonding pad extends beyond an edge of the respective solar cell; and electrically interconnecting the second portion of the bonding pad associated with a first solar cell with a second electrode of a directly adjacent second solar cell.

### BRIEF DESCRIPTION OF THE DRAWINGS

The present invention will be now described more fully hereinafter with reference to the accompanying drawings, in which some, but not all embodiments of the invention are shown. Drawings illustrating the embodiments are not-to-scale schematic representations. For the purpose of the present description and of the appended claims, all ranges include the maximum and minimum points disclosed and include any intermediate ranges therein, which may or may not be specifically enumerated herein.

FIG. 1 is a partial schematic plan view of an array of solar cells, according to an embodiment of the present invention

FIG. 2 is a cross-section of the array of solar cells shown in FIG. 1 taken along the line A-A.

FIG. 3 is a plan view of the flexible substrate at the end of the process step including the formation of bonding pads on the film substrate.

### DESCRIPTION OF THE PREFERRED EMBODIMENTS

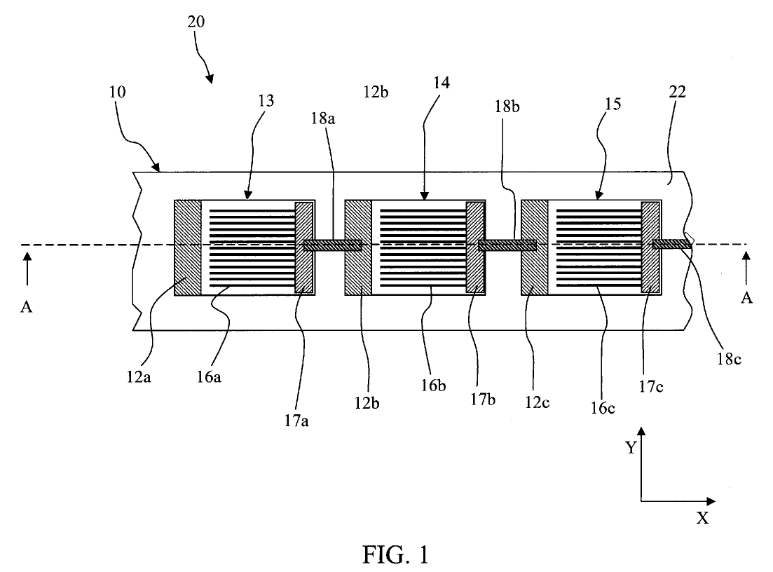

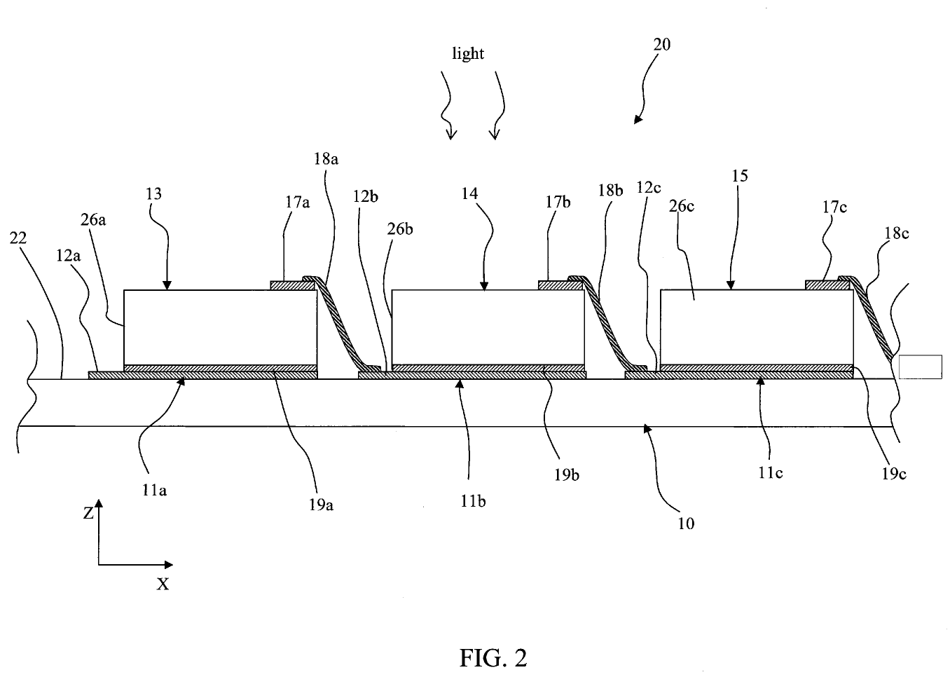

FIGS. 1 and 2 illustrates, respectively, a partial plan view and a cross-sectional view of a solar cell array arranged on a common flexible substrate and comprising a plurality of individual solar cells electrically interconnected. As used herein, the term “plurality” indicates “at least two”, and typically much larger than two (e.g., 50 to 100), where the number of individual cells in the array can widely vary depending on the application and on the output power required from the array. For simplicity, three individual solar cells 13, 14 and 15 of solar cell array 20 are illustrated in FIGS. 1 and 2. The cross-sectional view illustrated in FIG. 2 is taken along line A-A of FIG. 1 of the longitudinal “X” direction indicated in the figures and representing the main direction of arrangement of the solar cells in the array.

The solar cell array 20 can be part of a photovoltaic module, namely a packaged interconnected assembly of solar cells comprising one or more solar cell arrays.

The individual cells are mounted on a common electrically insulating substrate 10, in the preferred embodiments being made of a flexible material. Preferably, the insulating substrate 10 is a film in the form of an initially continuous strip or sheet of dielectric material, preferably made of a polyester, polyamide or polyimide material, such as Kapton®, a registered trademark by Du Pont. The insulating substrate 10 has a carrier surface 22 on which the individual cells are mounted. Thickness of the film substrate can be for example comprised between about 50 and 75 μm. A plurality of bonding pads are coated or metallized on the carrier surface 22 so as to form electrically conductive pads 11a, 11b, and 11c, made of a thin metal layer. In one embodiment, the metal layer is a Ti/Au/Ag sequence of layers.

For convenience of explanation and non-limitative purposes, the following description refers to a horizontal array of series-connected solar cells, in which the cross-sectional areas of the solar cells in the plane (X,Y) of the carrier surface 22 of the insulating substrate 10 have a regular shape, such as a rectangular or a square shape, and all cells have the same cross-sectional area. Solar cells 13, 14 and 15 have a vertical stacked structure, each cell comprising a respective active portion 26a, 26b, and 26c, in which the absorption of the sun light impinging the front surface of each cell takes place. The active portion (or absorption portion) of the respective cell is a semiconductor body in the form of a plurality of thin-film semiconductor layers, for example binary, ternary and/or quaternary alloys of III-V semiconductors. A front electrode is provided on the front surface exposed to radiation, namely the light-receiving surface, of each cell. As it is generally known, the front electrode should cover the smallest possible area of the front surface of the cell, for instance not more than 3-4% of the light-receiving surface. Conventionally, the front electrode of the solar cells can comprise a respective busbar portion 17a, 17b and 17c on a peripheral region of the front surface of the cell and a respective plurality of narrow fingers 16a, 16b, and 16c connected to the respective busbar portion. On the back side of the active portion of each cell, opposite to the front side, a respective back electrode 19a, 19b, and 19c is arranged. Preferably, the back electrode covers substantially the whole back surface of the active portion of each cell and defines a back contact area for each cell. Each back electrode 19a, 19b, and 19c is a metal layer, for instance a Ti/Pd/Au/Ag sequence of layers.

The solar cells of solar array 20 are interconnected on the same substrate by connecting the anode of one cell to the cathode of the directly adjacent cell (series connection). In the embodiments illustrated in the figures, the front electrode of each cell acts as a cathode and the back electrode acts as an anode.

A plurality of electrically conductive bonding pads 11a, 11b and 11c are provided on the carrier surface 22 of the substrate. Individual solar cells 13, 14 and 15 are electrically connected to a respective bonding pad 11a, 11b and 11c by attaching each back electrode (anode) 19a, 19b, and 19c to the respective bonding pad. In some embodiments, bonding of the back electrode can be performed by means of an electrically conductive adhesive or of a solder preform.

Back contacts in thin-film solar cells are generally very thin metallic layers, e.g., 2 to 5 μm thick layers, which can be for instance deposited by sputtering or evaporation on the back side of the active portion of the cell. Thin-film cells are fragile to handle and in attaching bonding wires or ribbons to the electrodes on the cell, the cell may tend to crack or break, or the thin electrode layer may be damaged when subjected to the pressure of welding or soldering during the process steps necessary for the interconnection, or may otherwise create a poor bond or an electrically unreliable or mechanically unstable connection.

In a one aspect of some embodiments of the present invention, the interconnection between the anode of one cell and the cathode of an adjacent cell takes place by electrically connecting the front electrode of a first cell to a bonding pad on which a second cell, adjacent to the first cell, is disposed. Each bonding pad has a surface area on the carrier surface 22 of the film substrate 10 which is larger than the surface area of the back electrode of the solar cell facing the bonding pad, i.e., the cell back contact area. The “excess” surface area of the bonding pad, which is uncovered by the solar cell, remains exposed for electrical connection.

The advantage of such an arrangement is that the welding or soldering process is not made directly to the fragile cell, but to the metal layer deposited on the thicker and more robust flexible substrate.

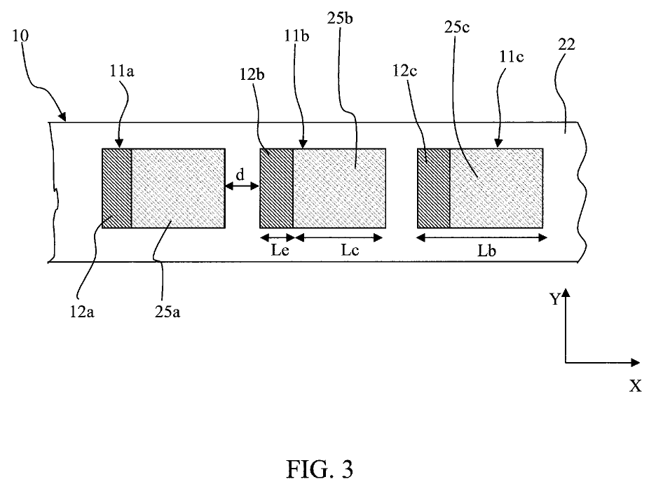

FIG. 3 illustrates a first step of the manufacturing process of the solar cell array, after which the plurality of bonding pads, 11a, 11b, 11c can be fabricated on the carrier surface 22 of the insulating substrate 10 by conventional methods for manufacturing printed circuit boards. In an embodiment, the formation of the plurality of bonding pads is made by deposition of a metal layer through a shadow mask. In another embodiment, formation of the plurality of bonding pads is performed by depositing a metal layer and by employing photolithographic techniques for the patterning of the deposited metal layer so as to define a plurality of metal regions. Each bonding pad is spaced apart from a directly adjacent bonding pad along the X direction by a distance, d, to electrically insulate one pad from another.

Bonding pads have a surface area in the plane (X,Y) of the carrier surface 22 of the substrate, the surface area having a first lateral side, L_{b}, extending along the X direction and a second lateral side extending along a direction transversal to the X direction. In the embodiment illustrated in the figures, the surface areas of bonding pads have a rectangular shape with the second lateral side extending along the Y direction, orthogonal to the X direction. FIG. 3 indicates with dashed area 25a, 25b and 25c the surface areas of respective bonding pads 11a, 11b and 11c covered by the solar cell, namely the first portions of the bonding pads corresponding to the back contact areas of the solar cells. The back contact areas 25a, 25b and 25c have a first lateral side, L, along the X direction shorter than the first lateral side, L_{b}, of the respective bonding pad and a second lateral side along the Y axis being substantially equal to the second lateral side of the respective bonding pad. The excess areas 12a, 12b, and 12c of respective bonding pads 11a, 11b and 11c are the second portions of the bonding pads not covered by the cells and thus exposed for electrical connection. These exposed regions protrudes horizontally from an edge of each cell, in the plane (X,Y), so as to form peripheral edge regions, which, in the embodiment shown in the figures, have rectangular shape. The length of the exposed regions along the X direction is indicated in FIG. 3 with Lₑ.

It is to be understood that the bonding pads can have different shapes, although, for convenience, rectangular shaped pads are illustrated in the embodiments described with reference to the figures.

Referring back to FIGS. 1 and 2, adjacent solar cells in the array are electrically interconnected by means of a short flexible ribbon 18a, 18b, and 18c bonded at one end to the exposed region of the bonding pad of one solar cell and at the other end to the front contact of another solar cell, being directly adjacent to the one solar cell and having the front contact proximal to the exposed region of the one solar cell along the X direction. In particular, one end of ribbon 18a is welded on exposed region 12b of cell 14 and the opposite end of the ribbon 18a is welded on cathode (busbar portion) 17a of adjacent cell 13. Likewise, ribbon 18b interconnects the exposed contact region 12c of the bonding pad 11c in correspondence of cell 15 with the cathode 17b of cell 14.

For example, interconnecting ribbons can be made of a metal, such as Ag or Kovar®, having a thickness of 25 μm.

Advantageously, the bonding pads formed on the flexible film can be produced with a thickness as large as 2 to 5 μm, thereby providing a robust and secure contact pad for the interconnection of adjacent cells. Preferably, the thickness of the bonding pads is comprised between 2 μm and 5 μm. Due to its intrinsic robustness, the exposed contact regions of the bonding pads can have a small linear dimension, Lₑ, along the solar cell array direction X, preferably Lₑ being selected to be just large enough to make a weld of the ribbon. For example, Lₑ can be selected within the range from 1 to 2 mm. Therefore, the spacing distance, Lₑ+d, between adjacent cells along the solar cell array direction X can be selected to be 10% or less of the linear dimension of the cell along the X axis. For example, for 2×2 cm² solar cells, the spacing distance between cells can be 2 mm or less.

The solar cell array configuration according to at least some embodiments of the invention permits to achieve a high packing density, e.g., 85% or even higher, as adjacent cells can be placed on the film substrate at a short distance in the direction of arrangement of the cells.

Furthermore, it is noted that, due to the robustness of the interconnecting pad formed in the film substrate, a ribbon with a relatively large thickness and/or width can be used, thereby making strong interconnections possible, for example by means of short flexible ribbons. It is however to be understood that the use of one or more bonding wires between the solar cells to implement an electrical interconnection is an alternative embodiment of the present invention. In the case of bonding wires, such wires may be ultrasonically welded to the respective electrodes on the solar cells.

Advantageously, anode and cathode terminals can be accessed from the front side of the solar cells.

In some embodiments, the solar cell array comprises an electrically insulating substrate having a carrier surface on which a plurality of electrically conductive bonding pads are provided, the bonding pads being laterally spaced from one another along a main direction; a plurality of solar cells, each solar cell of the plurality being disposed on a corresponding bonding pad of the plurality of bonding pads and including a light-receiving surface upon which light is incident, a front electrode placed on the light-receiving surface and a back electrode disposed on a back surface of the cell opposite to the light-receiving surface and having a first surface area, the back electrode facing and being electrically connected to the corresponding bonding pad, and a plurality of interconnecting leads, wherein the corresponding bonding pad has a second surface area on the carrier surface of the substrate larger than the first surface area of the back electrode, in such a way as to define an exposed contact region in the bonding pad not covered by the back electrode, and wherein an interconnecting lead of the plurality of interconnecting leads is connected from the front electrode of a first solar cell of the plurality of solar cells to an exposed contact region of a bonding pad corresponding to a directly adjacent second solar cell of said plurality.

Although the invention herein has been described with reference to particular embodiments, it is to be understood that these embodiments are merely illustrative of the principles and applications of the present invention. It is therefore to be understood that numerous modifications may be made to the illustrative embodiments and that other arrangements may be devised without departing from the spirit and scope of the present invention as defined by the appended claims.

The foregoing described embodiments depict different components contained within, or connected with, different other components. It is to be understood that such depicted arrangements are merely exemplary, and that in fact many other arrangements can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “operably connected” or “operably coupled” to each other to achieve the desired functionality.

While particular embodiments of the present invention have been shown and described, it will be understood by those skilled in the art that, based upon the teachings herein, changes and modifications may be made without departing from this invention and its broader aspects and, therefore, the appended claims are to encompass within their scope all such changes and modifications as are within the true spirit and scope of this invention. Furthermore, it is to be understood that the invention is solely defined by the appended claims. It will be understood by those within the art that, in general, terms used herein, and especially in the appended claims (e.g., in the bodies of the appended claims) are generally intended as “open” terms (e.g., the term “including” should be interpreted as “including but not limited to,” the term “having” should be interpreted as “having at least,” the term “includes” should be interpreted as “includes but is not limited to,” “comprise” and variations thereof, such as, “comprises” and “comprising” are to be construed in an open, inclusive sense, that is as “including, but not limited to,” etc.). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to inventions containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations. In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations).

1. A solar cell array comprising:
a substrate having a carrier surface on which a plurality of electrically conductive bonding pads are provided, the bonding pads being spaced from one another in a main direction;
a plurality of solar cells, each solar cell of the plurality including a first electrode bonded to a respective bonding pad so as to make electrical contact with a first portion of the respective bonding pad,
wherein each bonding pad comprises a second portion defining an exposed contact region not covered by the first electrode of the respective solar cell, and
wherein an interconnecting lead electrically connects the second portion of the bonding pad associated with a first solar cell of the plurality of solar cells with a second electrode of a directly adjacent second solar cell of the plurality.

2. The array of claim 1, wherein the substrate is an electrically insulating substrate.

3. The array of claim 1, wherein the substrate comprises a film made of flexible material.

4. The array of claim 1, wherein the substrate comprises a flexible polyimide film.

5. The array of claim 1, wherein the interconnecting lead is a flexible ribbon.

6. The array of claim 1, wherein each solar cell further comprises a light-receiving surface upon which light is incident and a front electrode placed on the light-receiving surface, and wherein the first electrode is a back electrode being arranged on a back surface of the solar cell opposite to the light-receiving surface.

7. The array of claim 6, wherein the interconnecting lead is connected from the front electrode of a first solar cell to the second portion of a bonding pad associated with a directly adjacent second solar cell, said second portion being proximal to the front electrode of the first solar cell along the main direction.

8. The array of claim 6, wherein the interconnecting lead is a ribbon that connects the front contact of the first solar cell with the second portion of the bonding pad associated with the directly adjacent second solar cell.

9. The array of claim 1, wherein the first electrode of each solar cell is a metal layer.

10. The array of claim 1, wherein each bonding pad is a metal layer.

11. The array of claim 1, wherein each bonding pad is a metal layer having a thickness ranging from 2 μm to 5 μm.

12. The array of claim 1, wherein each bonding pad has a rectangular shape defined by a first lateral side extending along the main direction and a second lateral side extending in a direction orthogonal to the main direction.

13. The array of claim 12, wherein the first electrode of each solar cell extends in the main direction less than the first lateral side of the respective bonding pad on which it is disposed so as to define a second portion of rectangular shape.

14. The array of claim 12, wherein the first electrode of each solar cell extends in the direction orthogonal to the main direction with a length substantially equal to the second lateral side of the respective bonding pad on which it is disposed.

15. The array of claim 1, wherein the second portion of each bonding pad has a length in the main direction comprised between 1 mm and 2 mm.

16. The array of claim 1, wherein the second portion of each bonding pad has a rectangular shape.

17. A method of assembling a solar cell array comprising:
providing a substrate;
forming on said substrate a plurality of spaced apart electrically conductive bonding pads;
bonding a solar cell to each of said bonding pads so that a first electrode of each of the solar cells makes electrical contact with a respective first portion of each bonding pad and a second portion of each bonding pad extends beyond an edge of the respective solar cell; and
electrically interconnecting the second portion of the bonding pad associated with a first solar cell with a second electrode of a directly adjacent second solar cell.

18. The method of claim 17, wherein the step of bonding a solar cell to each of said bonding pads is performed by gluing with an electrically conductive adhesive or by soldering with a solder preform.

19. The method of claim 17, wherein each bonding pad is a metal layer.

20. The method of claim 17, wherein the step of forming a plurality of spaced apart bonding pads is performed by depositing a metal layer through a shadow mask.

21. The method of claim 17, wherein the step of forming a plurality of bonding pads is performed by depositing a metal layer and by patterning the metal layer to form a plurality of spaced apart metal regions.

22. The method of claim 17, wherein the step of electrically interconnecting adjacent solar cells is performed by welding a first end of a flexible ribbon to the second portion of the bonding pad associated with a first solar cell and a second end of the flexible ribbon to the second electrode of a directly adjacent second solar cell.

23. The method of claim 17, wherein the step of electrically interconnecting adjacent solar cells is performed by ultrasonically welding a first end of at least one bonding wire to the second portion of the bonding pad associated with a first solar cell and a second end of the at least one bonding wire to the second electrode of a directly adjacent second solar cell.
